(19) United States
(12) Patent Application Publication
(10) Pub. No.: US 2006/0091493 A1
(43) Pub. Date: May 4, 2006

(54) LOCOS Schottky barrier contact structure and its manufacturing method

(75) Inventor: Ching-Yuan Wu, Hsinchu (TW)

Correspondence Address: DENNISON, SCHULTZ, DOUGHERTY & MACDONALD, 1727 KING STREET, SUITE 105, ALEXANDRIA, VA, 22314, US

(73) Assignee: SILICON-BASED TECHNOLOGY CORP.

(21) Appl. No.: 10/976,887

(22) Filed: Nov. 1, 2004

(51) Int. Cl. H01L 27/095; H01L 29/47; H01L 29/861; H01L 31/07

(52) U.S. Cl. 257/484; 257/471; 257/481; 257/483

(57) ABSTRACT

A LOCOS Schottky barrier contact structure of the present invention comprises a raised diffusion guard ring being surrounded by an outer LOCOS field oxide layer, a recessed semiconductor substrate being surrounded by the raised diffusion guard ring, a metal silicide layer being formed over the raised diffusion guard ring and the recessed semiconductor substrate, and a patterned metal layer being formed over a portion of the outer LOCOS field oxide layer and the metal silicide layer, wherein the raised diffusion guard ring is formed between an inner LOCOS field oxide layer and the outer LOCOS field oxide layer and the recessed semiconductor substrate is formed by removing the inner LOCOS field oxide layer. The LOCOS Schottky barrier contact structure offers the raised diffusion guard ring to eliminate junction curvature effect on reverse breakdown voltage and the outer LOCOS field oxide layer with a much better metal step coverage.

### BACKGROUND OF THE INVENTION

1. Field of the Invention

The present invention relates generally to a Schottky barrier contact structure and its manufacturing method and, more particularly, to a LOCOS Schottky barrier contact structure and its manufacturing method.

2. Description of the Related Art

A Schottky barrier diode comprising a metal-semiconductor contact is known to be a majority-carrier diode and is therefore used as a high-speed switching diode or a high-frequency rectifier. For a Schottky barrier diode used as a switching power diode, major design issues are concentrated on reverse breakdown voltage (V_{B}), reverse leakage current (I_{R}), forward current (I_{f}) and forward voltage (V_{f}). In general, a diffusion guard ring is required to reduce the reverse leakage current due to edge of the metal-semiconductor contact and to relax soft breakdown due to high edge field. However, the diffusion guard ring may produce junction curvature effect on the reverse breakdown voltage and a deeper junction depth of the diffusion guard ring is required to reduce junction curvature effect. As a consequence, it is difficult to simultaneously obtain a higher reverse breakdown voltage and a lower forward voltage (V_{f}) for a given metal-semiconductor contact area.

FIG. 1 shows a schematic cross-sectional view of a conventional Schottky barrier contact structure with a diffusion guard ring, in which a p⁺ diffusion guard ring 105 is formed in a surface portion of a n⁻/n⁺ epitaxial silicon substrate 101/100 through a diffusion window (not shown) formed between two patterned field oxide layers 102a; a metal silicide layer 103 being acted as a Schottky barrier metal is formed on a portion of the diffusion guard ring 105 and the n⁻/n⁺ epitaxial silicon substrate 101/100 surrounded by a patterned step borosilicate glass (BSG) layer 106a; a patterned metal layer 104a is formed on a portion of the patterned field oxide layer 102a, the patterned step borosilicate glass layer 106a, and the metal silicide layer 103; and a backside metal layer (not shown) being acted as an ohmic contact metal is formed on the n⁺ silicon substrate 100.

From FIG. 1, it is clearly seen that three masking photoresist steps are required to implement a Schottky barrier diode, wherein a first masking photoresist step is used to define a diffusion window of the p⁺ diffusion guard ring 105; a second masking photoresist step is used to remove the patterned field oxide layer 102a (not shown) and a portion of the step borosilicate glass layer 106a (not shown) for forming the metal silicide layer 103; and a third masking photoresist step is used to form the patterned metal layer 104a. Apparently, it is difficult to simultaneously remove the patterned field oxide layer 102a and the step borosilicate glass layer 106 (not shown) outside of the second masking photoresist. Similarly, it is very difficult to simultaneously remove the patterned field oxide layer 102a and the step borosilicate glass layer 106a using anisotropic dry etching without producing a serious trenching on the p+ diffusion guard ring 105 and the exposed n⁻/n⁺ epitaxial silicon substrate 101/100 outside of the second masking photoresist. Therefore, the width of the p⁺ diffusion guard ring 105 must be kept to be larger and the junction depth of the p+ diffusion guard ring 105 must be kept to be deeper. As a consequence, the cell size of the prior art is larger and the forward voltage (V_{f}) for a given forward current is also larger.

It is therefore a major objective of the present invention to offer a LOCOS Schottky barrier contact structure with a raised diffusion guard ring for obtaining higher reverse breakdown voltage and lower forward voltage.

It is another objective of the present invention to offer a LOCOS Schottky barrier contact structure with a better metal step coverage.

It is a further objective of the present invention to offer a LOCOS Schottky barrier contact structure with a minimized diffusion guard ring area and an optimized cell area.

### SUMMARY OF THE INVENTION

The present invention discloses a LOCOS Schottky barrier contact structure and its manufacturing method. The LOCOS Schottky barrier contact structure comprises a semiconductor substrate of a first conductivity type comprised of a lightly-doped epitaxial silicon layer being formed on a heavily-doped silicon substrate, a raised diffusion guard ring of a second conductivity type being formed between an outer LOCOS field oxide layer and an inner LOCOS field oxide layer, a recessed semiconductor substrate being surrounded by the raised diffusion guard ring, a metal silicide layer being formed over a semiconductor surface surrounded by the outer LOCOS field oxide layer, including the raised diffusion guard ring and the recessed semiconductor substrate surrounded by the raised diffusion guard ring, and a patterned metal layer being formed over a portion of the outer LOCOS field oxide layer and the metal silicide layer, wherein the inner LOCOS field oxide layer is removed through a masking photoresist step after performing a diffusion process to form the raised diffusion guard ring. The LOCOS Schottky barrier contact structure of the present invention offers the raised diffusion guard ring to eliminate junction curvature effect on reverse breakdown voltage, the recessed semiconductor substrate for forming a Schottky barrier contact to reduce parasitic series resistance, and the outer LOCOS field oxide layer to have a much better metal step coverage.

### BRIEF DESCRIPTION OF THE DRAWINGS

FIG. 1 shows a schematic cross-sectional view of a Schottky barrier contact structure of the prior art.

FIG. 2A through FIG. 2G show process steps and their schematic cross-sectional views of fabricating a LOCOS Schottky barrier contact structure of the present invention.

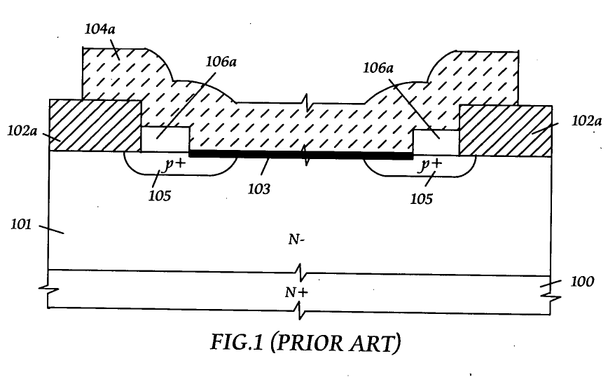

### DETAILED DESCRIPTION OF THE PREFERRED EMBODIMENTS

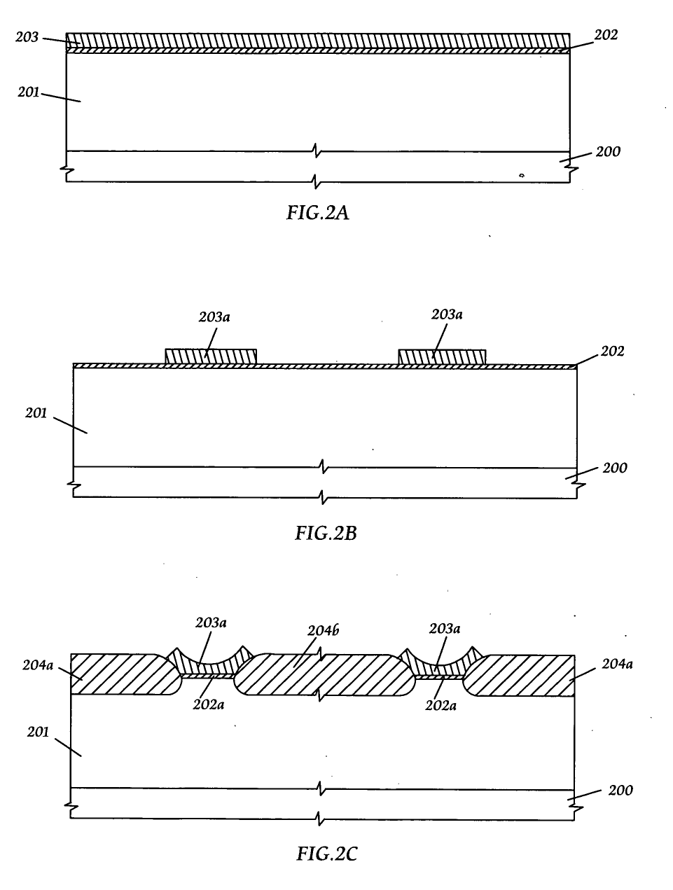

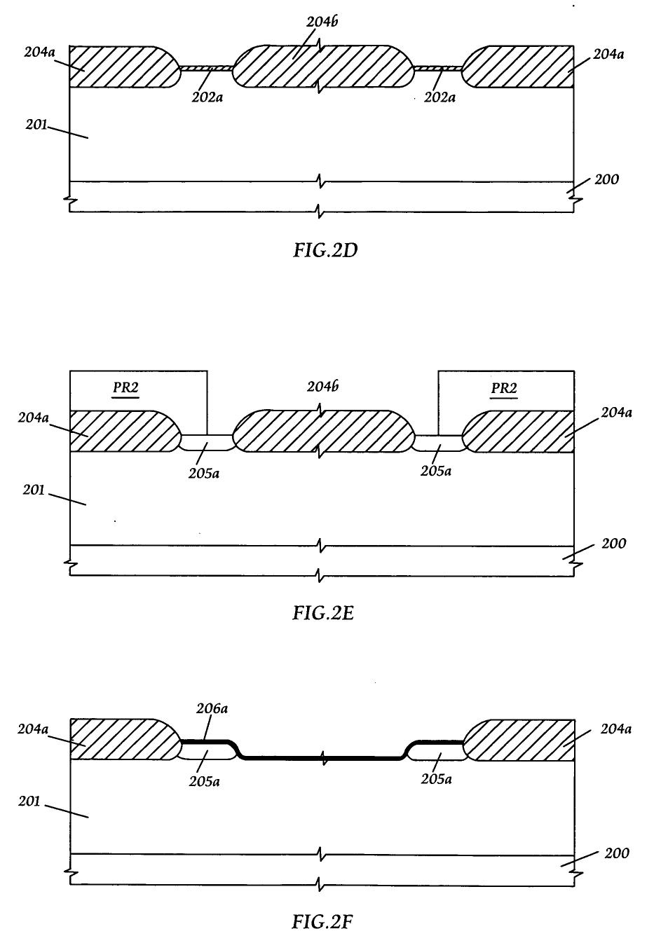

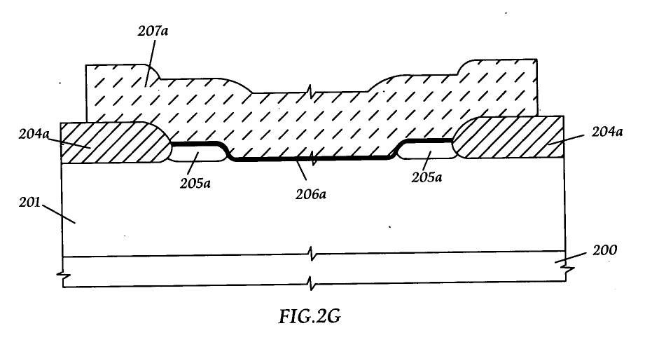

Referring now to FIG. 2A through FIG. 2G, there are shown process steps and their schematic cross-sectional views of fabricating a LOCOS Schottky barrier contact structure of the present invention.

FIG. 2A shows that a pad oxide layer 202 is formed on a semiconductor substrate 201/200 of a first conductivity type; and subsequently, a silicon nitride layer 203 is formed on the pad oxide layer 202. The pad oxide layer 202 is a thermal silicon dioxide layer grown on the semiconductor substrate 201/200 in a dry oxygen ambient and its thickness is preferably between 100 Angstroms and 500 Angstroms. The silicon nitride layer 203 is formed by low-pressure chemical vapor deposition (LPCVD) and its thickness is preferably between 500 Angstroms and 1500 Angstroms. The semiconductor substrate 201/200 comprises a lightly-doped epitaxial silicon layer 201 being formed on a heavily-doped silicon substrate 200, in which the lightly-doped epitaxial silicon layer 201 has a thickness between 2 μm and 35 μm and a doping concentration between 10¹⁴/cm³ and 10¹⁷/cm³; the heavily-doped silicon substrate 200 has a doping concentration between 10¹⁹/cm³ and 5×10²⁰/cm³ and a thickness between 250 μm and 800 μm, depending on wafer size.

FIG. 2B shows that a first masking photoresist (PR1) step (not shown) is performed to pattern the silicon nitride layer 203, in which the silicon nitride layer 203 outside of a guard ring region is removed by anisotropic dry etching and therefore the patterned silicon nitride layer 203a in the guard ring region is remained.

FIG. 2C shows that the pad oxide layer 202 outside of the patterned silicon nitride layer 203a is removed by using buffered hydrofluoric acid or dilute hydrofluoric acid and a local oxidation of silicon (LOCOS) process is performed in a steam or wet oxygen ambient to form an inner LOCOS field oxide layer 204b and an outer LOCOS field oxide layer 204a. The thickness of the inner/outer LOCOS field oxide layer 204b/204a is preferably between 6000 Angstroms and 10000 Angstroms and the oxidation temperature is between 1000 and 1200. It should be noted that the local oxidation of silicon can be performed without removing the pad oxide layer 202 outside of the patterned silicon nitride layer 203a.

FIG. 2D shows that the patterned silicon nitride layer 203a is removed by using hot-phosphoric acid or anisotropic dry etching.

FIG. 2E shows that ion implantation is performed in a self-aligned manner by implanting doping impurities of a second conductivity type across the patterned pad oxide layer 202a into a surface portion of the semiconductor substrate 201/200; the drive-in process is then performed to form a raised diffusion guard ring 205a; the patterned pad oxide layer 202a is subsequently removed by using dilute hydrofluoric acid or buffered hydrofluoric acid and the outer/inner field oxide layers 204a/204b are simultaneously etched; and thereafter, a second masking photoresist (PR2) step is performed to cover the outer LOCOS field oxide layer 204a and a portion of the raised diffusion guard ring 205a. It should be noted that a conventional thermal diffusion process using a liquid source, a solid source or a gas source can be performed instead of ion implantation by removing the patterned pad oxide layer 202a. It should be emphasized that the junction depth of the raised diffusion guard ring 205a is controlled to approximately equal to or slightly deeper than a bottom surface level of the outer/inner LOCOS field oxide layer 204a/204b. The raised diffusion guard ring 205a can be a heavily-doped diffusion guard ring, a moderately-doped diffusion guard ring or a heavily-doped diffusion guard ring formed within a moderately-doped diffusion guard ring.

FIG. 2F shows that the inner LOCOS field oxide layer 204b is removed by using buffered hydrofluoric acid; the second masking photoresist (PR2) is then stripped and a wafer cleaning process is then performed; and subsequently, a metal silicide layer 206a is formed on an exposed silicon surface by using a well-known self-aligned silicidation process, including the raised diffusion guard ring 205a and an recessed semiconductor substrate 201/200 surrounded by the raised diffusion guard ring 205a. The metal silicide layer 206a is preferably a refractory metal silicide layer, such as CrSi₂, NiSi, CoSi₂, TiSi₂, MoSi₂, TaSi₂, PtSi₂, PdSi₂, or WSi₂, etc.

FIG. 2G shows that a patterned metal layer 207a is formed on a portion of the outer LOCOS field oxide layer 204a and the metal silicide layer 206a by using a third masking photoresist (PR3) step (not shown). The patterned metal layer 207a comprises a metal layer on a barrier metal layer. The metal layer comprises aluminum (Al), silver (Ag) or gold (Au). The barrier metal layer comprises a refractory metal layer or a refractory metal nitride layer.

It should be noted that the heavily-doped silicon substrate 200 is back-lapped (not shown) to a predetermined thickness in order to reduce parasitic series resistance and a backside ohmic contact is then performed (not shown).

Apparently, the features and advantages of the present invention can be summarized below:

(a) The LOCOS Schottky barrier contact structure of the present invention offers a raised diffusion guard ring to eliminate or reduce junction curvature effect on reverse breakdown voltage, so a higher reverse breakdown voltage can be easily obtained.

(b) The LOCOS Schottky barrier contact structure of the present invention offers a recessed semiconductor substrate surrounded by a raised diffusion guard ring for a Schottky barrier metal contact to reduce parasitic series resistance due to the lightly-doped epitaxial silicon layer for a given reverse breakdown voltage, so a lower forward voltage for a given forward current can be obtained without increasing cell area.

(c) The LOCOS Schottky barrier contact structure of the present invention offers an outer LOCOS field oxide layer and a removed inner LOCOS field oxide layer to provide a much better metal step coverage.

(d) The LOCOS Schottky barrier contact structure of the present invention offers a minimized cell area with a minimized raised diffusion guard ring and an optimized Schottky barrier contact area for given reverse breakdown voltage, forward voltage and forward current.

While the present invention has been particularly shown and described with a reference to the present examples and embodiments as considered as illustrative and not restrictive. Moreover, the present invention is not to be limited to the details given herein, it will be understood by those skilled in the art that various changes in forms and details may be made without departure from the true spirit and scope of the present invention

What is claimed is:

1. A LOCOS Schottky barrier contact structure, comprising:
a semiconductor substrate of a first conductivity type, wherein the semiconductor substrate comprises a lightly-doped epitaxial silicon layer being formed on a heavily-doped silicon substrate;
a raised diffusion guard ring of a second conductivity type being formed between an outer LOCOS field oxide layer and an inner LOCOS field oxide layer, wherein the inner LOCOS field oxide layer is removed to form a recessed semiconductor substrate surrounded by the raised diffusion guard ring;
a metal silicide layer being formed over the raised diffusion guard ring surrounded by the outer LOCOS field oxide layer and the recessed semiconductor substrate surrounded by the raised diffusion guard ring; and
a patterned metal layer being formed over a portion of the outer LOCOS field oxide layer and the metal silicide layer.

2. The LOCOS Schottky barrier contact structure according to claim 1, wherein the outer and inner LOCOS field oxide layers are formed by a local oxidation of silicon (LOCOS) process in a steam or wet oxygen ambient.

3. The LOCOS Schottky barrier contact structure according to claim 1, wherein the raised diffusion guard ring comprises a heavily-doped diffusion guard ring, a moderately-doped diffusion guard ring or a heavily-doped diffusion guard ring formed within a moderately-doped diffusion guard ring.

4. The LOCOS Schottky barrier contact structure according to claim 1, wherein the raised diffusion guard ring is formed in a self-aligned manner by ion implantation of doping impurities across a pad oxide layer between the outer LOCOS field oxide layer and the inner LOCOS field oxide layer.

5. The LOCOS Schottky barrier contact structure according to claim 1, wherein the raised diffusion guard ring is formed in a self-aligned manner by a thermal diffusion process using a liquid source, a solid source or a gas source through a diffusion window formed between the outer LOCOS field oxide layer and the inner LOCOS field oxide layer.

6. The LOCOS Schottky barrier contact structure according to claim 1, wherein the metal silicide layer comprises a refractory metal suicide layer formed by a self-aligned silicidation process.

7. The LOCOS Schottky barrier contact structure according to claim 1, wherein the patterned metal layer comprises a metal layer on a barrier metal layer.

8. A LOCOS Schottky barrier contact structure, comprising:
a semiconductor substrate of a first conductivity type, wherein the semiconductor substrate comprises a lightly-doped epitaxial silicon layer being formed on a heavily-doped silicon substrate;
a guard ring being formed between an outer LOCOS field oxide layer and an inner LOCOS field oxide layer by using a local oxidation of silicon (LOCOS) process, wherein the guard ring is doped in a self-aligned manner by using ion implantation to form a raised diffusion guard ring of a second conductivity type;
a recess semiconductor substrate being formed by removing the inner LOCOS field oxide layer;
a refractory metal silicide layer being formed over the raised diffusion guard ring surrounded by the outer LOCOS field oxide layer and the recessed semiconductor substrate surrounded by the raised diffusion guard ring; and
a patterned metal layer being formed over a portion of the outer LOCOS field oxide layer and the refractory metal silicide layer.

9. The LOCOS Schottky barrier contact structure according to claim 8, wherein the lightly-doped epitaxial silicon layer has a doping concentration between 10¹⁴/cm³ and 10¹⁷/cm³ and a thickness between 2 μm and 35 μm.

10. The LOCOS Schottky barrier contact structure according to claim 8, wherein the outer and inner LOCOS field oxide layers being formed by the local oxidation of silicon (LOCOS) process are grown in a steam or wet oxygen ambient to have a thickness between 6000 Angstroms and 10000 Angstroms.

11. The LOCOS Schottky barrier contact structure according to claim 8, wherein the raised diffusion guard ring is a heavily-doped diffusion guard ring, a moderately-doped diffusion guard ring or a heavily-doped diffusion guard ring formed within a moderately-doped diffusion guard ring.

12. The LOCOS Schottky barrier contact structure according to claim 8, wherein the refractory metal silicide layer is formed by a self-aligned silicidation process.

13. The LOCOS Schottky barrier contact structure according to claim 8, wherein the patterned metal layer comprises a metal layer on a barrier metal layer.

14. A LOCOS Schottky barrier contact structure, comprising:
a semiconductor substrate of a first conductivity type, wherein the semiconductor substrate comprises a lightly-doped epitaxial silicon layer being formed on a heavily-doped silicon substrate;
a guard ring being formed between an outer LOCOS field oxide layer and an inner LOCOS field oxide layer by using a local oxidation of silicon (LOCOS) process in a steam or wet oxygen ambient, wherein the guard ring is doped in a self-aligned manner by using a thermal diffusion process to form a raised diffusion guard ring of a second conductivity type;
a recessed semiconductor substrate being formed by removing the inner LOCOS field oxide layer;
a refractory metal silicide layer being formed over the raised diffusion guard ring surrounded by the outer LOCOS field oxide layer and the recessed semiconductor substrate surrounded by the raised diffusion guard ring, wherein the refractory metal silicide layer is formed by a self-aligned silicidation process; and
a patterned metal layer being formed over a portion of the outer LOCOS field oxide layer and the refractory metal silicide layer.

15. The LOCOS Schottky barrier contact structure according to claim 14, wherein the outer and inner LOCOS field oxide layers have a thickness between 6000 Angstroms and 10000 Angstroms.

16. The LOCOS Schottky barrier contact structure according to claim 14, wherein the thermal diffusion process comprises a thermal doping process using a liquid source, a solid source or a gas source.

17. The LOCOS Schottky barrier contact structure according to claim 14, wherein the guard ring is defined by patterning a silicon nitride layer on a pad oxide layer using a first masking photoresist step.

18. The LOCOS Schottky barrier contact structure according to claim 14, wherein the inner LOCOS field oxide layer is removed after doping the guard ring by using a second masking photoresist step.

19. The LOCOS Schottky barrier contact structure according to claim 14, wherein the patterned metal layer comprises a silver (Ag), aluminum (Al) or gold (Au) layer on a barrier metal layer and is patterned by a third masking photoresist step.

20. The LOCOS Schottky barrier contact structure according to claim 14, wherein the refractory metal disilicide layer comprises one chosen from CrSi₂, NiSi, CoSi₂, TiSi₂, MoSi₂, TaSi₂, PtSi₂, PdSi₂ and WSi₂.
